(19) United States
(12) Patent Application Publication
(10) Pub. No.: US 2023/0170662 A1
(43) Pub. Date: Jun. 1, 2023

(54) LIGHT EMITTING DEVICE, LIGHT SOURCE DEVICE, AND OPTICAL FIBER LASER

(71) Applicant: FURUKAWA ELECTRIC CO., LTD., Tokyo (JP)

(72) Inventor: Yuta ISHIGE, Tokyo (JP)

(73) Assignee: FURUKAWA ELECTRIC CO., LTD., Tokyo (JP)

(21) Appl. No.: 18/160,396

(22) Filed: Jan. 27, 2023

Related U.S. Application Data
(63) Continuation of application No. PCT/JP2021/028850, filed on Aug. 3, 2021.

(30) Foreign Application Priority Data
Aug. 7, 2020 (JP) 2020-135046

(51) Int. Cl. H01S 3/04; H01S 3/042; H01S 3/067; H01S 3/094; H01S 3/0941

(52) U.S. Cl. CPC H01S 3/0407; H01S 3/042; H01S 3/067; H01S 3/0941; H01S 3/094042; H01S 5/4025

(57) ABSTRACT

A light emitting device includes: a plurality of light emitting elements that are aligned in a first direction; and a base that includes a plurality of mounting surfaces that are aligned in the first direction and on which the respective light emitting elements are mounted; a bottom surface that extends in a second direction that is inclined with respect to the first direction on back sides of the plurality of mounting surfaces; and a refrigerant passage that is arranged between the plurality of mounting surfaces and the bottom surface and in which a refrigerant flows, the refrigerant passage including a first section that extends in the first direction along the plurality of light emitting elements.

### REFERENCE TO RELATED APPLICATIONS

This application is a continuation of International Application No. PCT/JP2021/028850, filed on Aug. 3, 2021 which claims the benefit of priority of the prior Japanese Patent Application No. 2020-135046, filed on Aug. 7, 2020, the entire contents of which are incorporated herein by reference.

### BACKGROUND OF THE INVENTION

The present disclosure relates to a light emitting device, a light source device, and an optical fiber laser.

In the relater art, a light emitting device that includes stepped mounting surfaces that are arranged on a base, reflects laser light that comes from a light emitting element mounted on each of the mounting surfaces by a mirror mounted on each of the mounting surfaces toward a certain direction along the mounting surfaces, spatially multiplexes the laser light, and couples the multiplexed laser light is known (for example, International Publication No. WO/2017/122792).

### SUMMARY OF THE INVENTION

In this kind of the light emitting device, in some cases, a refrigerant passage through which a refrigerant for cooling the light emitting elements may be arranged in the base along a bottom surface located opposite to the mounting surface of the base.

However, in the configuration as described above, some light emitting elements are located close to the refrigerant passage and other light emitting elements are located distant from the refrigerant passage. In this case, in the light emitting elements located distant from the refrigerant passage, it may become difficult to achieve a cooling effect of the refrigerant. In other words, variation in the cooling effect of the refrigerant on each of the light emitting elements may increase.

Therefore, it is desirable to provide a light emitting device, a light source device, and an optical fiber laser capable of reducing variation in the cooling effect of the refrigerant on each of the light emitting elements, for example.

In some embodiments, a light emitting device includes: a plurality of light emitting elements that are aligned in a first direction; and a base that includes a plurality of mounting surfaces that are aligned in the first direction and on which the respective light emitting elements are mounted; a bottom surface that extends in a second direction that is inclined with respect to the first direction on back sides of the plurality of mounting surfaces; and a refrigerant passage that is arranged between the plurality of mounting surfaces and the bottom surface and in which a refrigerant flows, the refrigerant passage including a first section that extends in the first direction along the plurality of light emitting elements.

In some embodiments, a light emitting device includes: a plurality of light emitting elements that are aligned in a first direction; and a base that includes a plurality of mounting surfaces that are aligned in the first direction and on which the respective light emitting elements are mounted; and a refrigerant passage in which a refrigerant flows, the refrigerant passage including a first section that extends in the first direction along the plurality of light emitting elements.

In some embodiments, a light source device includes: the light emitting device.

In some embodiments, an optical fiber laser includes: the light source device.

The above and other objects, features, advantages and technical and industrial significance of this disclosure will be better understood by reading the following detailed description of presently preferred embodiments of the disclosure, when considered in connection with the accompanying drawings.

### BRIEF DESCRIPTION OF THE DRAWINGS

FIG. 1 is a schematic configuration diagram of a light emitting device of one embodiment;

FIG. 2 is an exemplary and schematic perspective view of a base of the light emitting device of the embodiment;

FIG. 3 is an exemplary and schematic perspective view of a refrigerant passage of the base of the light emitting device of the embodiment;

FIG. 4 is an exemplary and schematic plan view of the base of the light emitting device of the embodiment;

FIG. 5 is a cross-sectional view cut along a line V-V in FIG. 4;

FIG. 6 is an enlarged view of a VI portion in FIG. 5;

FIG. 7 is an exemplary and schematic perspective view of a light emitting device of a modification of the embodiment;

FIG. 8 is a schematic configuration diagram of a light source device including the light emitting devices of the embodiment; and

FIG. 9 is a schematic configuration diagram of an optical fiber laser including the light source devices of the embodiment.

### DETAILED DESCRIPTION

Exemplary embodiments of the disclosure are disclosed below. Configurations of the embodiments described below, and operation and results (effects) achieved by the configurations are mere example. The disclosure may be embodied by configurations other than those disclosed in the embodiments below. Further, according to the disclosure, it is possible to achieve at least one of various effects (including derivative effects) that are achieved by the configurations.

The embodiments described below include the same configurations. Therefore, according to the configurations of each of the embodiments, it is possible to achieve the same operation and effects based on the same configurations. Furthermore, in the following, the same components are denoted by the same reference symbols, and repeated explanation may be omitted.

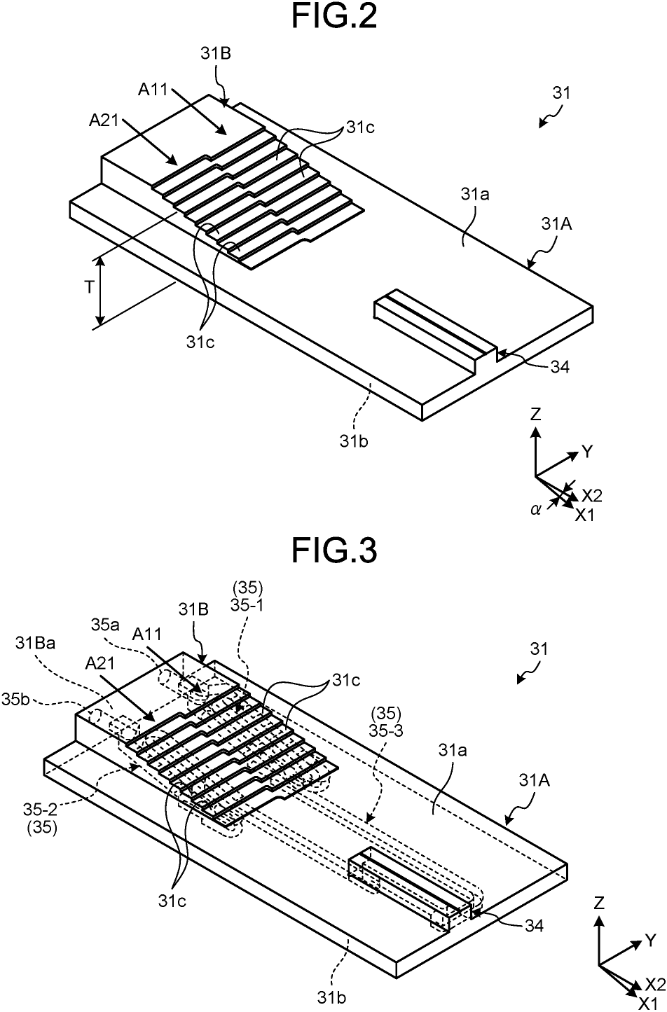

In each of the drawings, an X1 direction is represented by an arrow X1, an X2 direction is represented by an arrow X2, a Y direction is represented by an arrow Y, and a Z direction is represented by an arrow Z. The X2 direction, the Y direction, and the Z direction cross one another and are perpendicular to one another. Furthermore, the X1 direction and the Y direction cross each other and are perpendicular to each other. Moreover, in the coordinate system illustrated in the present embodiment, an angular difference between the X2 direction and the X1 direction is α (0° < α < 90°, see FIG. 2). In other words, the X2 direction is inclined with respect to the X1 direction. Furthermore, an angular difference between the X1 direction and the Z direction is 90°+α.

Moreover, in the present specification, ordinal numbers are assigned, for the sake of convenience, to distinguish components, members, parts, and the like, and do not indicate priority or order.

### Embodiment

Entire configuration of light emitting device

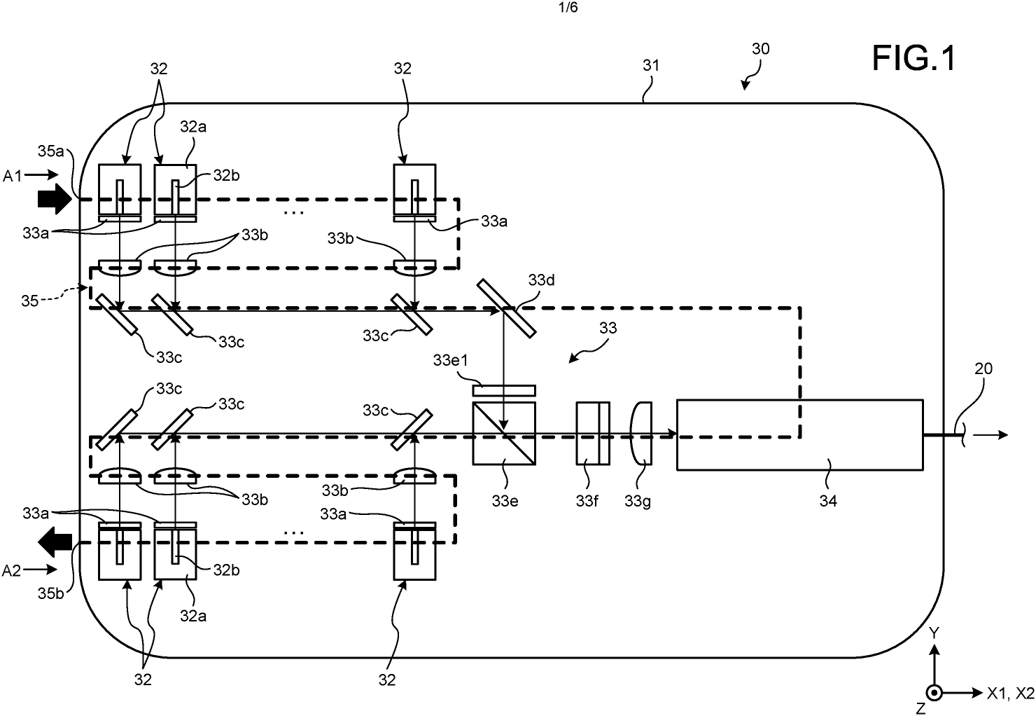

FIG. 1 is a schematic configuration diagram of a light emitting device 30 of the embodiment, and is a plan view of an inside of the light emitting device 30 when viewed in a direction opposite to the Z direction while a cover is removed. The light emitting device 30 may be referred to as a light source device.

As illustrated in FIG. 1, the light emitting device 30 includes a base 31, an optical fiber 20 that is fixed to the base 31, a plurality of light emitting units 32, and a photosynthesis unit 33 that synthesizes light coming from the plurality of light emitting units 32.

The optical fiber 20 is an output optical fiber, and fixed to the base 31 via a support unit 34 that supports an end portion (not illustrated) of the optical fiber.

The support unit 34 may be integrally configured with the base 31 as a part of the base 31, or the support unit 34 that may be configured as a different member from the base 31 may be mounted on the base 31 via a fixture, such as a screw, for example.

The base 31 is made of a certain material with high thermal conductivity, such as a copper-base material or an aluminum-base material, for example. The base 31 is covered by a cover (not illustrated). The optical fiber 20, the light emitting units 32, the photosynthesis unit 33, and the support unit 34 are housed and sealed in a housing chamber that is formed between the base 31 and the cover.

In the base 31, step surfaces 31c (see FIG. 2) are arranged for each of arrays A1 and A2, in each of which the plurality of light emitting units 32 are aligned at a predetermined interval (for example, a constant interval) in the X1 direction, such that the positions of the light emitting units 32 are deviated in the Z direction along a direction opposite to the X1 direction. Each of the light emitting units 32 is mounted on each of the step surfaces 31c. The X1 direction is one example of a first direction. Further, the step surfaces 31c are one example of mounting surfaces.

The light emitting units 32 are, for example, chip-on submounts. Each of the light emitting units 32 includes a submount 32a and a light emitting element 32b that is mounted on the submount 32a. The light emitting element 32b is, for example, a semiconductor laser chip. The plurality of light emitting elements 32b emit light at the same wavelength (single wavelength), for example.

The light that is output from the plurality of light emitting elements 32b is synthesized by the photosynthesis unit 33. The photosynthesis unit 33 includes optical components, such as collimator lenses 33a and 33b, mirrors 33c and 33d, a combiner 33e, and condensing lenses 33f and 33g.

The collimator lens 33a collimates light in the Z direction (fast axis direction), and the collimator lens 33b collimates light in the X2 direction (slow axis direction). The collimator lens 33a is, for example, mounted on the submount 32a and integrated with the light emitting unit 32. The collimator lens 33b is mounted on the step surface 31c on which the corresponding light emitting unit 32 is mounted.

The mirror 33c causes the light coming from the collimator lens 33b to travel toward the combiner 33e. The mirror 33c is mounted on the step surface 31c on which the corresponding light emitting units 32 and the corresponding collimator lens 33b are mounted. In other words, the light emitting unit 32, the collimator lens 33b through which light coming from the light emitting element 32b included in the light emitting unit 32 passes, and the mirror 33c that reflects the light coming from the collimator lens 33b are mounted on the same step surface 31c. In other words, for each of the arrays A1 and A2, the light emitting unit 32, the collimator lens 33b, and the mirror 33c that are aligned in the Y direction are mounted on the same step surface 31c. Meanwhile, the position of the step surface 31c in the Z direction and the size of the mirror 33c in the Z direction are set so as not to interfere with light that comes from the different mirror 33c. Further, in the following, the light emitting unit 32, the collimator lens 33b, and the mirror 33c that are mounted on the step surface 31c may be simply referred to as mounted components. Furthermore, the light emitting unit 32, the collimator lens 33b, and the mirror 33c need not always be mounted on the same step surface 31c (plane surface).

The combiner 33e combines light coming from the two arrays A1 and A2, and outputs the light toward the condensing lens 33f. The light coming from the array A1 is input to the combiner 33e via the mirror 33d and a half-wave plate 33e1, and the light coming from the array A2 is directly input to the combiner 33e. The half-wave plate 33e1 rotates a plane of polarization of the light coming from the array A1. The combiner 33e may also be referred to as a polarization synthesis element.

The condensing lens 33f condenses light in the Z direction (fast axis direction). The condensing lens 33g condenses light coming from the condensing lens 33f in the Y direction (slow axis direction), and optically couples the light to an end portion of the optical fiber 20.

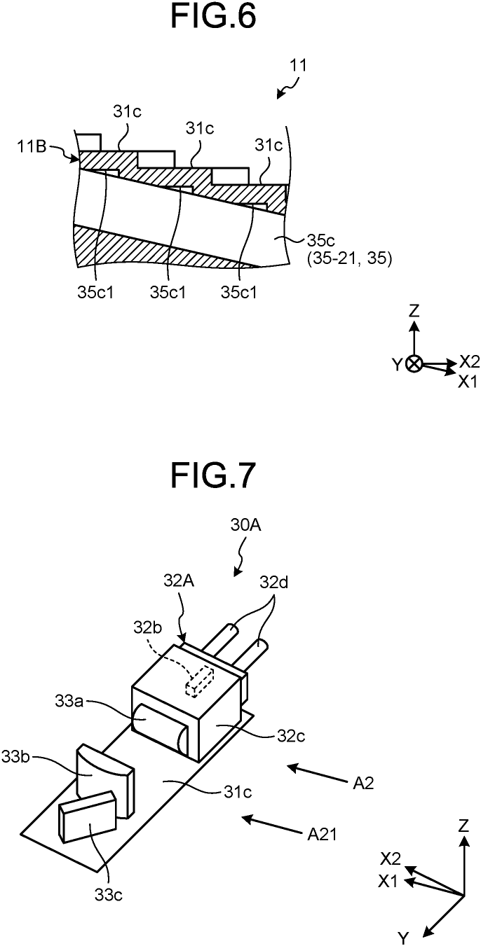

Further, in the base 31, a refrigerant passage 35 for cooling the plurality of light emitting units 32, the support unit 34, the condensing lenses 33f and 33g, the combiner 33e, and the like is arranged. In the refrigerant passage 35, for example, a refrigerant, such as coolant, flows. The refrigerant passage 35 passes by a mounting surface of each of the components of the base 31, for example, passes below or near the mounting surface, and an inner surface 35c (see FIGS. 5 and 6) of the refrigerant passage 35 and the refrigerant in the refrigerant passage 35 are thermally connected to the components and the parts to be cooled, in other words, the light emitting units 32, the support unit 34, the condensing lenses 33f and 33g, and the combiner 33e. Heat exchange is performed between the refrigerant and the components via the base 31, so that the components are cooled.

### Configuration of Base

FIG. 2 is a perspective view of the base 31. As illustrated in FIG. 2, the base 31 includes a plate-shaped part 31A and a protruding part 31B.

The plate-shaped part 31A has a quadrilateral (rectangular) plate shape that is elongated in the X2 direction and that is made thin in the Z direction. The plate-shaped part 31A includes an end surface 31a in the Z direction and an end surface 31b in a direction opposite to the Z direction. Each of the end surfaces 31a and 31b is spread while crossing the Z direction, and is spread in the X2 direction and the Y direction. The X2 direction may be referred to as a longitudinal direction, the Y direction may be referred to as a transverse direction (width direction), and the Z direction may be referred to as a thickness direction or a height direction. The end surface 31b is one example of a bottom surface. The X2 direction is one example of a second direction.

The mirror 33d, the combiner 33e (the half-wave plate 33e1), the condensing lenses 33f and 33g, and the like (see FIG. 1) are mounted on the end surface 31a of the plate-shaped part 31A.

The protruding part 31B protrudes from the end surface 31a in the Z direction in an approximately half region of the plate-shaped part 31A on an opposite side in the X2 direction. The protruding part 31B includes the plurality of step surfaces 31c. The plurality of step surfaces 31c are arranged at equal intervals in the X1 direction.

Each of the step surfaces 31c crosses the Z direction and is spread in a perpendicular manner.

The protruding part 31B includes the plurality of arrays A11 and A21 in each of which the plurality of the step surfaces 31c are aligned in the X1 direction. The arrays A11 and A21 are deviated from each other in the Y direction. In each of the arrays A11 and A21, the step surfaces 31c extend in the Y direction and also extend in the X2 direction. A length of each of the step surfaces 31c in the Y direction is longer than a length (width) in the X2 direction.

The end surface 31b extends in the X2 direction that is inclined with respect to the X1 direction. Further, the end surface 31b is arranged on back sides of the plurality of step surfaces 31c in the base 31. Therefore, in each of the arrays A11 and A21, a length T (height or thickness) of each of the step surfaces 31c from the end surface 31b is reduced along the X2 direction.

On each of the step surfaces 31c in the array A11, the light emitting unit 32, the collimator lens 33b that collimates light coming from the light emitting unit 32, and the mirror 33c that reflects the light coming from the collimator lens 33b (see FIG. 1 for all of the components) that are included in the array A1 are mounted. Although not illustrated in FIG. 2, the light emitting unit 32 mounted on each of the step surfaces 31c in the array A11 is aligned in the X1 direction, the collimator lens 33b mounted on each of the step surfaces 31c in the array A11 is aligned in the X1 direction, and the mirror 33c mounted on each of the step surfaces 31c in the array A11 is aligned in the X1 direction.

In each of the step surfaces 31c in the array A21, the light emitting unit 32, the collimator lens 33b that collimates light coming from the light emitting units 32, and the mirror 33c that reflects the light coming from the collimator lens 33b (see FIG. 1 for all of the components) that are included in the array A2 are mounted. Although not illustrated in FIG. 2, the light emitting units 32 mounted on the respective step surfaces 31c in the array A21 are aligned in the X1 direction, the collimator lenses 33b mounted on the respective step surfaces 31c in the array A21 are aligned in the X1 direction, and the mirrors 33c mounted on the respective step surfaces 31c in the array A21 are aligned in the X1 direction.

Furthermore, on each of the step surfaces 31c, the light emitting unit 32, the collimator lens 33b, and the mirror 33c that correspond to one another are mounted so as to be aligned in the Y direction.

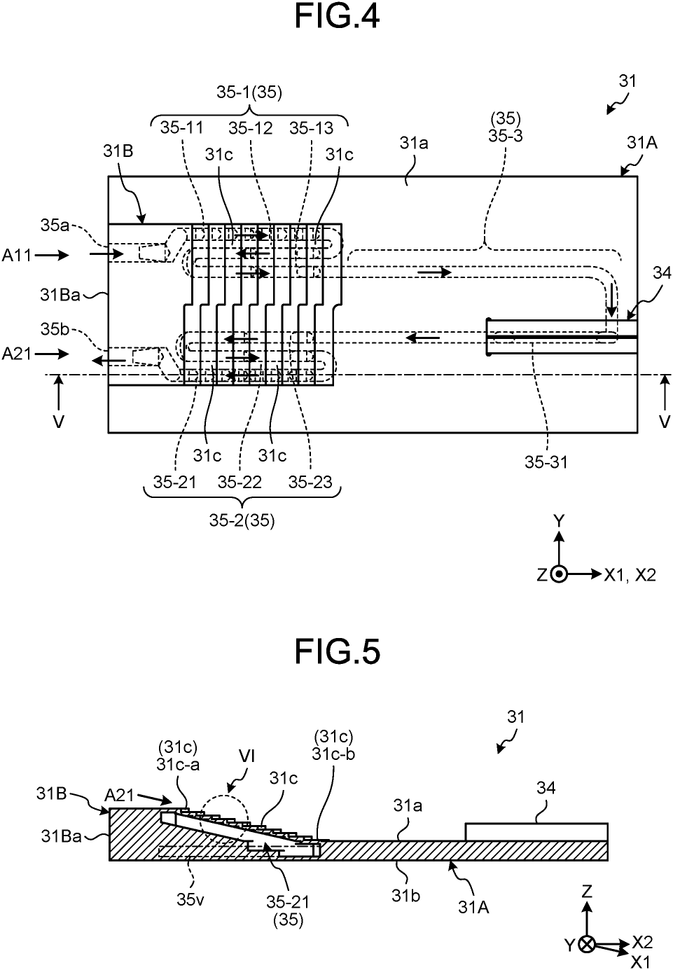

FIG. 3 is a perspective view illustrating the refrigerant passage 35 that is formed in the base 31, and FIG. 4 is a plan view of the refrigerant passage 35 formed in the base 31 when viewed in a direction opposite to the Z direction.

The refrigerant passage 35 is a single passage in the base 31. A refrigerant that is introduced from an inlet 35a that is arranged in an end portion 31Ba of the protruding part 31B in a direction opposite to the X2 direction is discharged from an outlet 35b that is arranged in the end portion 31Ba.

As illustrated in FIG. 3, the refrigerant passage 35 includes a section 35-1 that overlaps with the array A11 in the Z direction in the protruding part 31B, in other words, between the end surface 31b and the plurality of step surfaces 31c, a section 35-3 that is arranged in the plate-shaped part 31A, and a section 35-2 that overlaps with the array A21 in the Z direction in the protruding part 31B. The refrigerant passage 35 is extended from the inlet 35a to the outlet 35b via the section 35-1, the section 35-3, and the section 35-2 in this order.

Furthermore, as illustrated in FIG. 4, the section 35-1 includes a section 35-11 that at least partially overlaps with the light emitting units 32 in the Z direction, a section 35-12 that at least partially overlaps with the collimator lenses 33b in the Z direction, and a section 35-13 that at least partially overlaps with the mirrors 33c in the Z direction. The sections 35-11, 35-12, and 35-13 extend in the X1 direction and are parallel to one another. Furthermore, the sections 35-11, 35-12, and 35-13 are aligned in the Y direction. The section 35-11 and the section 35-12 are connected to each other at a folded part of a U-shape, and the section 35-12 and the section 35-13 are connected to each other at a folded part of a U-shape. The section 35-1 is one example of a first section that corresponds to the array A1 of the light emitting units 32 and the array A11 of the step surfaces 31c. Meanwhile, the plurality of sections 35-11, 35-12, and 35-13 may be arranged at equal intervals or at different intervals in the Y direction. Furthermore, each of the light emitting units 32, the collimator lenses 33b, and the mirrors 33c on the step surfaces 31c in the array A11 may be arranged so as to overlap with a region between adjacent two of the sections 35-11, 35-12, and 35-13 in the Z direction.

The section 35-2 includes a section 35-21 that at least partially overlaps with the light emitting units 32 in the Z direction, a section 35-22 that at least partially overlaps with the collimator lenses 33b in the Z direction, and a section 35-23 that at least partially overlaps with the mirrors 33c in the Z direction. The sections 35-21, 35-22, and 35-23 extend in the X1 direction and are parallel to one another. Furthermore, the sections 35-21, 35-22, and 35-23 are aligned in the Y direction. The section 35-21 and the section 35-22 are connected to each other at a folded part of a U-shape, and the section 35-22 and the section 35-23 are connected to each other at a folded part of a U-shape. The section 35-2 is one example of a first section that corresponds to the array A2 of the light emitting units 32 and the array A21 of the step surfaces 31c. Meanwhile, the plurality of sections 35-21, 35-22, and 35-23 may be arranged at equal intervals or at different intervals in the Y direction. Furthermore, each of the light emitting units 32, the collimator lenses 33b, and the mirrors 33c on the step surfaces 31c in the array A21 may be arranged so as to overlap with a region between adjacent two of the sections 35-21, 35-22, and 35-23 in the Z direction.

Moreover, the section 35-3 bends inside the plate-shaped part 31A. Furthermore, the section 35-3 includes a section 35-31 that overlaps with the support unit 34 in the Z direction. The section 35-31 extends in the X2 direction. Meanwhile, the X2 direction may be referred to as a longitudinal direction of the support unit 34.

In the configuration as described above, the refrigerant passage 35 is extended from the inlet 35a to the outlet 35b via the section 35-11, the section 35-12, the section 35-13, the section 35-3 (the section 35-31), the section 35-23, the section 35-22, and the section 35-21 in this order. The refrigerant flows in the X1 direction in the section 35-11, flows in a direction opposite to the X1 direction in the section 35-12, and flows in the X1 direction in the section 35-13. In the section 35-3, the refrigerant flows in a direction opposite to the X2 direction. Furthermore, the refrigerant flows in a direction opposite to the X1 direction in the section 35-23, flows in the X1 direction in the section 35-22, and flows in a direction opposite to the X1 direction in the section 35-21.

FIG. 5 is a cross-sectional view cut along a line V-V in FIG. 4. In the cross section in FIG. 5, the section 35-21 is illustrated. The section 35-21 extends in the X1 direction along the array A21 of the plurality of step surfaces 31c that are aligned in the X1 direction. Therefore, a distance between each of the step surfaces 31c and the section 35-21 is approximately the same. If, as indicated by a double-dotted line, a refrigerant passage 35v is arranged so as to extend in the X2 direction along the end surface 31b, a distance between a step surface 31c-a that is located on an end portion of the array A21 in the direction opposite to the X1 direction and the refrigerant passage 35v is longer than a distance between a step surface 31c-b that is located on an end portion of the array A21 in the X1 direction and the refrigerant passage 35v. In other words, depending on the positions of the step surfaces 31c, the cooling effect of the refrigerant that passes through the refrigerant passage 35v on the mounted components on each of the step surfaces 31c may become different (vary). In this regard, as described above, in the present embodiment, it is possible to approximately equalize the distance between each of the step surfaces 31c and the section 35-21 (the refrigerant passage 35), so that it is possible to reduce variation in the cooling effect of the refrigerant on the mounted components on each of the step surfaces 31c. Meanwhile, although not illustrated in the drawing, the cross sections of the light emitting units 32, the collimator lenses 33b, and the mirrors 33c perpendicular to the Y direction that passes through each of the arrays have the same cross-sectional shapes as illustrated in FIG. 5. In other words, the distance from each of the step surfaces 31c to the sections 35-11, 35-12, 35-13, 35-22, and 35-23 is approximately the same, so that it is possible to achieve the same effects even in the sections 35-11, 35-12, 35-13, 35-22, and 35-23. Meanwhile, the refrigerant passage 35 may be formed by arranging a hole in the protruding part 31B, or by covering a concave groove that is arranged on at least one of members, which constitute a part of the base 31, by the other one of the members on a bonding surface.

A layout of each of the sections in the refrigerant passage 35, the number of the sections, and the order of connection of the sections are not limited to the example as described above. Furthermore, the light emitting units 32 generate the largest amount of heat among the mounted components, and therefore it is desirable that any of the sections in the refrigerant passage 35 overlaps with the arrays A1 and A2 of the light emitting units 32 in the Z direction. However, the sections and the arrays need not always overlap with each other in the Z direction. For example, the refrigerant passage 35 may include two sections that extend in the X1 direction and that are adjacent to each other in the Y direction, the base 31 may include a separation wall between the two sections, and at least one of the arrays A1 and A2 is arranged so as to come into contact with and overlap with the separation wall in the Z direction. Furthermore, the sections in the refrigerant passage 35 need not always overlap with the array of the collimator lenses 33b and the array of the mirrors 33c in the Z direction.

FIG. 6 is an enlarged view of a VI portion in FIG. 5. As illustrated in FIG. 6, concave portions 35c1 are arranged on the inner surface 35c of the refrigerant passage 35. By arranging the concave portions 35c1 as described above, it is possible to disturb the flow of the refrigerant in the refrigerant passage 35, and prevent stagnation. With this configuration, it is possible to further reduce variation in the cooling effect of the refrigerant caused by the position in the refrigerant passage 35. The concave portions 35c1 are one example of an uneven structure. Meanwhile, it may be possible to arrange convex portions (not illustrated) as the uneven structure on the inner surface 35c instead of the concave portions 35c1, or it may be possible to arrange both of the concave portions 35c1 and the convex portions. Further, the uneven structure may be arranged at a position different from the section 35-21 in the refrigerant passage 35.

Furthermore, as illustrated in FIG. 6, in the present embodiment, the concave portions 35c1 as the uneven structure are arranged in a region near the step surfaces 31c in the inner surface 35c. The region near the step surfaces 31c is a region that is located on back sides of the step surfaces 31c in the inner surface 35c across a part (separation wall) of the base 31, and is a region located at an end portion of the inner surface 35c in the Z direction. The region near the step surfaces 31c is thermally connected to the separation wall, which is located in a space formed with the step surfaces 31c, and the mounted components via the step surfaces 31c. In other words, the region near the step surfaces 31c constitutes a part of a heat transmission passage between the mounted components and the refrigerant. Therefore, with this configuration, an area of a region that comes into contact with the refrigerant in the inner surface 35c and that performs heat exchange with the refrigerant, in other words, an area of contact with the refrigerant, increases, so that it is possible to achieve an effect of further promoting heat exchange between the refrigerant and the mounted components.

Thus, as described above, in the present embodiment, the base 31 includes the plurality of step surfaces 31c (mounting surfaces) that are aligned in the X1 direction (first direction), and the end surface 31b (bottom surface) that extends in the X2 direction (second direction) inclined with respect to the X1 direction on the back sides of the plurality of step surfaces 31c. The light emitting units 32 (light emitting elements) mounted on the respective step surfaces 31c are aligned in the X1 direction. Further, in the base 31, the refrigerant passage 35 in which the refrigerant flows is arranged between the plurality of step surfaces 31c and the end surface 31b. Furthermore, the refrigerant passage 35 includes the sections 35-11, 35-12, 35-13, 35-21, 35-22, and 35-23 (first sections) that extend in the X1 direction along the plurality of light emitting units 32.

With this configuration, for example, it is possible to further reduce or substantially eliminate variation in the distance between the refrigerant and each of the light emitting units 32, so that it is possible to further reduce variation in the cooling effect of the refrigerant on each of the light emitting units 32.

Furthermore, in the present embodiment, for example, the refrigerant passage 35 includes the plurality of sections 35-11, 35-12, 35-13 (first sections) corresponding to the array A1 of the light emitting units 32, and includes the plurality of sections 35-21, 35-22, and 35-23 (first sections) corresponding to the array A2 of the light emitting units 32. With this configuration, for example, it is possible to further improve the cooling effect of the refrigerant on each of the light emitting units 32 as compared to a case in which only a single first section is arranged for each of the arrays A1 and A2 of the light emitting units 32.

Moreover, in the present embodiment, for example, the light emitting device 30 includes the arrays A1 and A2 each including the plurality of light emitting units 32, and the refrigerant passage 35 includes the sections 35-1 and 35-2 (first sections) that extend along the arrays A1 and A2. With this configuration, for example, it is possible to further improve the cooling effect of the refrigerant as compared to a case in which only a single shared first section is arranged for the plurality of arrays A1 and A2.

Furthermore, in the present embodiment, for example, the plurality of sections 35-11, 35-12, 35-13, 35-21, 35-22, and 35-23 are connected in series. If the refrigerant passage 35 includes a plurality of sections that are arranged in a parallel manner, a difference in flow resistance or a difference in a flow rate may occur in the plurality of sections due to a certain cause, such as adhesion of dust or corrosion, that occurs over time, and the cooling effect of the refrigerant on each of the light emitting units 32 may become different (vary). In this regard, according to the present embodiment, for example, the plurality of sections 35-11, 35-12, 35-13, 35-21, 35-22, and 35-23 are connected in series, so that a difference in a flow rate due to a cause that may occur over time in each of the sections 35-11, 35-12, 35-13, 35-21, 35-22, and 35-23 is less likely to occur, so that the cooling effect of the refrigerant on each of the light emitting units 32 is less likely to vary.

Moreover, in the present embodiment, for example, the sections 35-11, 35-12, 35-13, 35-21, 35-22, and 35-23 are arranged such that the refrigerant that passes through the sections and the plurality of light emitting units 32 are thermally connected to each other. With this configuration, for example, it is possible to more reliably cool the plurality of light emitting units 32 by the refrigerant that passes through each of the sections 35-11, 35-12, 35-13, 35-21, 35-22, and 35-23 via a part of the base 31 serving as a heat transmission passage.

### Modification of Light Emitting Unit

FIG. 7 is a partial perspective view of a light emitting device 30A according to a modification, and is a perspective view of a light emitting unit 32A, the collimator lens 33b, and the mirror 33c that are mounted on the step surface 31c in the array A21.

As illustrated in FIG. 7, the light emitting unit 32A includes a case 32c, the collimator lens 33a that is partially exposed from the case 32c, and the light emitting element 32b and a submount (not illustrated) that are housed in the case 32c. The light emitting element 32b is mounted on the submount. The light emitting element 32b and the submount are housed in the case 32c in a hermetically sealed manner. The case 32c may be referred to as a housing.

The light emitting element 32b emits laser light in the Y direction inside the case 32c. The laser light emitted from the light emitting element 32b passes through the collimator lens 33a, is output to the outside of the light emitting unit 32A, and reaches the mirror 33c via the collimator lens 33b. Further, leads 32d for supplying a driving current to the light emitting element 32b protrudes from the case 32c in a direction opposite to the Y direction.

The light emitting device 30 of the embodiment as described above may include the light emitting units 32A of the present modification, instead of the light emitting units 32. With this configuration, it is possible to improve protection of the light emitting elements 32b against gas or dust.

Meanwhile, in the present modification, the light emitting unit 32A, the collimator lens 33b, and the mirror 33c are mounted on the same step surface 31c (plane surface), but need not always be mounted on the same plane surface.

### Configuration of Light Source Device

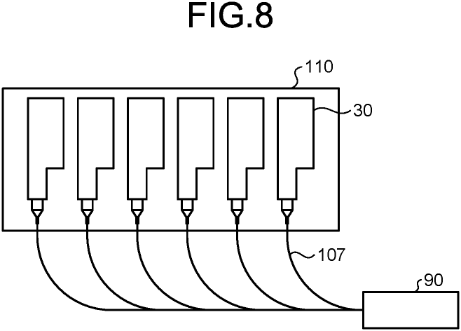

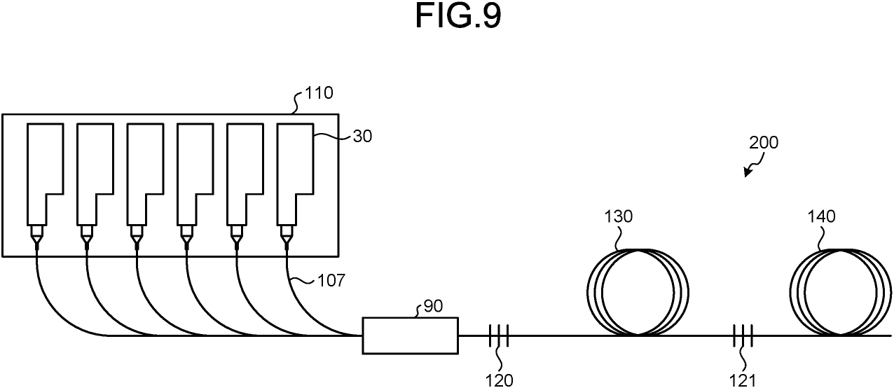

FIG. 8 is a configuration diagram of a light source device 110 of the embodiment on which the light emitting devices 30 are mounted. The light source device 110 includes, as a pumping light source, the plurality of light emitting devices 30. Light (laser light) emitted from the plurality of light emitting devices 30 is transmitted to a combiner 90 that serves as a light coupling unit via optical fibers 107. Output ends of the optical fibers 107 are connected to a plurality of input ports of the combiner 90 that includes a plurality of inputs and a single output. Meanwhile, the light source device 110 need not always include the plurality of light emitting devices 30, but it is sufficient to include at least the single light emitting device 30.

### Configuration of Optical Fiber Laser

FIG. 9 is a configuration diagram of an optical fiber laser 200 on which the light source device 110 illustrated in FIG. 8 is mounted. The optical fiber laser 200 includes the light source device 110 and the combiner 90 illustrated in FIG. 8, a rare earth-added optical fiber 130, and an output-side optical fiber 140. High-reflectivity fiber brag gratings 120 and 121 are arranged on an input end and an output end of the rare earth-added optical fiber 130.

The input end of the rare earth-added optical fiber 130 is connected to an output end of the combiner 90, and an input end of the output-side optical fiber 140 is connected to the output end of the rare earth-added optical fiber 130. Meanwhile, it may be possible to adopt a different configuration as an incidence unit that inputs the laser light output from the plurality of light emitting devices 30 to the rare earth-added optical fiber 130, instead of the combiner 90. For example, it may be possible to arrange the optical fibers 107 in output units of the plurality of light emitting devices 30 in a parallel manner, and input the laser light output from the plurality of optical fibers 107 to the input end of the rare earth-added optical fiber 130 by using an incidence unit, such as an optical system including a lens or the like. The rare earth-added optical fiber 130 is one example of an optical amplification fiber.

According to the light emitting device 30, the light source device 110, and the optical fiber laser 200 as described above, it is possible to further reduce variation in the cooling effect of the refrigerant on each of the light emitting elements.

Thus, the embodiments of the disclosure have been described above, but the embodiments as described above are mere example, and do not limit the scope of the disclosure. The embodiments as described above may be embodied in various different forms, and various omission, replacement, combinations, and modifications may be made within the scope of the disclosure. Furthermore, each of the specifications, such as the configurations and the shapes (structures, types, directions, models, sizes, lengths, widths, thicknesses, heights, numbers, arrangement, positions, materials, and the like) may be appropriately changed.

According to the disclosure, for example, it is possible to obtain a light emitting device, a light source device, and an optical fiber laser capable of reducing variation in the cooling effect of the refrigerant on each of the light emitting elements.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A light emitting device comprising:
a plurality of light emitting elements that are aligned in a first direction; and
a base that includes
a plurality of mounting surfaces that are aligned in the first direction and on which the respective light emitting elements are mounted;
a bottom surface that extends in a second direction that is inclined with respect to the first direction on back sides of the plurality of mounting surfaces; and
a refrigerant passage that is arranged between the plurality of mounting surfaces and the bottom surface and in which a refrigerant flows,
the refrigerant passage including a first section that extends in the first direction along the plurality of light emitting elements.

2. The light emitting device according to claim 1, wherein the refrigerant passage includes, as the first section, a plurality of first sections for a single array of the plurality of light emitting elements that are aligned in the first direction.

3. The light emitting device according to claim 1, further comprising:
a plurality of arrays each including the plurality of light emitting elements that are aligned in the first direction, wherein
the refrigerant passage includes, as the first section, a plurality of first sections along the respective arrays.

4. The light emitting device according to claim 2, wherein the plurality of first sections are connected in series.

5. The light emitting device according to claim 2, wherein the plurality of first sections are parallel to one another.

6. The light emitting device according to claim 1, wherein an inner surface of the base has an uneven structure configured to cause a refrigerant to swirl, the inner surface forming the refrigerant passage.

7. The light emitting device according to claim 6, wherein the uneven structure is arranged in at least a region near the light emitting element in the inner surface.

8. A light emitting device comprising:
a plurality of light emitting elements that are aligned in a first direction; and
a base that includes
a plurality of mounting surfaces that are aligned in the first direction and on which the respective light emitting elements are mounted; and
a refrigerant passage in which a refrigerant flows,
the refrigerant passage including a first section that extends in the first direction along the plurality of light emitting elements.

9. The light emitting device according to claim 2, wherein the first section is arranged such that a refrigerant in the first section and the plurality of light emitting elements are thermally connected to each other.

10. The light emitting device according to claim 8, wherein the first section is arranged such that a refrigerant in the first section and the plurality of light emitting elements are thermally connected to each other.

11. A light source device comprising:
the light emitting device according to claim 1.

12. A light source device comprising:
the light emitting device according to claim 8.

13. An optical fiber laser comprising:
the light source device according to claim 11.

14. An optical fiber laser comprising:
the light source device according to claim 12.
